(19) United States
(12) Patent Application Publication
(10) Pub. No.: US 2025/0266316 A1
(43) Pub. Date: Aug. 21, 2025

(54) HEAT SPREADER WITH PINS FOR THE THERMAL MANAGEMENT IMPROVEMENT OF CHIPLETS

(71) Applicant: International Business Machines Corporation, Armonk, NY (US)

(72) Inventors: Keiji Matsumoto, Yokohama-shi (JP); Mukta Ghate Farooq, Hopewell Junction, NY (US); John Knickerbocker, Monroe, NY (US)

(21) Appl. No.: 18/581,566

(22) Filed: Feb. 20, 2024

(51) Int. Cl. H01L 23/367; H01L 21/48; H01L 23/00; H01L 25/065

(52) U.S. Cl. CPC H01L 23/3675; H01L 21/4882; H01L 24/16; H01L 24/32; H01L 24/33; H01L 24/73; H01L 25/0655; H01L 2224/16225; H01L 2224/32225; H01L 2224/32245; H01L 2224/33181; H01L 2224/73204; H01L 2224/73253

(57) ABSTRACT

A structure that includes at least one chiplet, a heat spreader located over the at least one chiplet, a laminate located under the at least one chiplet, and at least one pin extending between the heat spreader and the laminate and located near the at least one chiplet. The at least one pin is adapted to dissipate heat from the at least one chiplet.

### BACKGROUND

The present disclosure generally relates to a structure of a semiconductor package, and more particularly to a structure of a semiconductor package that includes heat dissipation.

Electronic signals are carried by electrical current through conductors and transistors in a large-scale integrated circuit (IC) fabricated on semiconductor substrate. Heat is generated in electronic semiconductor ICs. Heat spreaders, including drop-in heat spreaders, heat sinks, and heat pipes have been used in the past to enhance thermal performances of IC packages. Thermal enhancement methods rely on heat removal from the entire chip or from the entire package.

### SUMMARY

According to some embodiments of the disclosure, there is provided a structure. The structure includes at least one chiplet, a heat spreader located over the at least one chiplet, a laminate located under the at least one chiplet, and at least one pin extending between the heat spreader and the laminate and located near the at least one chiplet. The at least one pin is adapted to dissipate heat from the at least one chiplet.

According to some embodiments of the disclosure, there is provided a system. The system includes a plurality of chiplet, a heat spreader located over the plurality of chiplets, a laminate located under the plurality of chiplets, a heat sink located over the heat spreader, and a plurality of pins extending between the heat spreader and the laminate and located near the plurality of chiplets. The plurality of pins are adapted to dissipate heat from the plurality of chiplets.

According to some embodiments of the disclosure, there is provided a method. The method includes an operation of providing a heat spreader. Another operation is providing laminate layer including a plurality of chiplets. A further operation is attaching a first end of a plurality of pins to a lower surface of the heat spreader. Yet another operation is contacting a second end of the plurality of pins to the laminate layer surrounding the plurality of chiplets. The plurality of pins conduct heat from the plurality of chiplets in the laminate layer to the heat spreader.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 illustrates a side, cut-away view of a semiconductor structure including a heat dissipation mechanism, in accordance with an embodiment of the disclosure.

FIG. 2 illustrates a top-down view of the semiconductor structure of FIG. 1, not including a heat spreader (as in FIG. 1), in accordance with an embodiment of the disclosure.

FIG. 3 illustrates a magnified portion of the top-down view of FIG. 2, in accordance with an embodiment of the disclosure.

FIG. 4 illustrates a magnified portion of the top-down view of FIG. 2, in accordance with an embodiment of the disclosure.

FIG. 5 illustrates a side, cut-away view of a semiconductor structure including a heat dissipation mechanism, in accordance with an embodiment of the disclosure.

FIGS. 6A-6C illustrate examples of pins that can be included in a semiconductor structure including a heat dissipation mechanism, in accordance with an embodiment of the disclosure.

FIG. 7 illustrates a perspective view of a portion of a semiconductor structure and a close-up view of another portion of the semiconductor structure, used in simulations, in accordance with an embodiment of the disclosure.

FIG. 8 illustrates a perspective view of a portion of a semiconductor structure and a close-up view of another portion of the semiconductor structure, used in simulations, in accordance with an embodiment of the disclosure.

FIGS. 9A-9B illustrate a perspective view and a top view, respectively, of a model of an interconnection layer of a semiconductor structure, in accordance with an embodiment of the disclosure.

FIGS. 10A-10B illustrate a perspective view and a top view, respectively, of an example of a power and ground plane of a semiconductor structure, in accordance with an embodiment of the disclosure.

FIG. 11 illustrates a flow chart of a method of making or manufacturing a semiconductor structure, in accordance with an embodiment of the disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

It will be readily understood that the components of the present embodiments, as generally described and illustrated in the Figures herein, can be arranged and designed in a wide variety of different configurations. Thus, the following detailed description of the embodiments of the apparatus, system, method, and computer program product of the present embodiments, as presented in the Figures, is not intended to limit the scope of the embodiments, as claimed, but is merely representative of selected embodiments.

Reference throughout this specification to “a select embodiment,” “one embodiment,” or “an embodiment” means that a particular feature, structure, or characteristic described in connection with the embodiment is included in at least one embodiment. Thus, appearances of the phrases “a select embodiment,” “in one embodiment,” or “in an embodiment” in various places throughout this specification are not necessarily referring to the same embodiment. It should be understood that the various embodiments can be combined with one another, and that any one embodiment can be used to modify another embodiment.

The illustrated embodiments will be best understood by reference to the drawings, wherein like parts are designated by like numerals throughout. The following description is intended only by way of example, and simply illustrates certain selected embodiments of devices, systems, and processes that are consistent with the embodiments as claimed herein.

Aspects of the present disclosure relate generally to a structure of a semiconductor package. More particularly, the present disclosure provides a semiconductor structure including a heat spreader with pins that enhance heat dissipation. While the present disclosure is not necessarily limited to such applications, various aspects of the disclosure can be appreciated through a discussion of various examples using this context.

Due to increased functionality of electronic devices, the heat that must be dissipated in the electronic devices has grown dramatically in recent years. Poor heat dissipation in packaged electronic devices limits device performance and the size of the module. In some cases, the need for an external heat sink to manage the thermal dissipation has limited the size of a small module or end-product, which is not in tune with key technology trends. Electronic devices are growing smaller in size so that ever smaller modules containing an ever-increasing density of devices are desired. Heat dissipation is an increasing problem and improved thermal management is required. Particularly, a simple, low-cost heat dissipation method is desired.

In three-dimensional integration (3Di) of semiconductor devices, heat density is increased. Also, in backside power delivery networks (BSPDNs) there is additional thermal resistance between transistors and a cooling path. It is desirable for an additional thermal solution be included in such semiconductor devices that does not significantly interfere with electrical performance and mechanical performance of the semiconductor devices.

Providing adequate thermal management for electronic packages is important, especially in multi-chip packages (MCPs) and stacked die architectures. In the case of stacked die architectures, thermal resistance through the thickness of the die is particularly limited. As such, conventional integrated heat spreader (IHS), architectures that interface with a backside surface of the dies can be limited since the thermal resistance through the thickness of the dies is high. As such, hot spots in the underlying package substrate can be generated. The presence of hot spots makes it more likely that the junction temperature (Tⱼ) of the die can be exceeded.

An IHS, or “heat spreader,” can be a metal exterior lid of a central processor unit (CPU). It can serve as a protective shell around the processing silicon and a pathway for heat to be exchanged between the CPU and a cooler or heat sink that can be located near the IHS.

Embodiments of the present disclosure include a semiconductor structure with a heat spreader and pins extending between the heat spreader and a laminate layer and surrounding chiplets, which is adapted for thermal conduction from the chiplets in the laminate layer to the heat spreader. The heat spreader can be thermally coupled to chiplets by the pins. The pins can be inserted into the laminate layer around the chiplets. The pins can, alternatively, be located atop, rest on top or sit on top of the laminate layer around the chiplets. The pins can be surrounded by a dielectric material in order to prevent electrical influence. Multiple pins can support heat removal from one or more chiplets. Locations of the pins can be optimized, considering one or more hot spots in the one or more chiplets. The pins can contact edges of one or more chiplets. Appropriate placement of the pins can permit signal wiring in package and/or bridge chips for effective high bandwidth communication links while also supporting heat removal. A coefficient of thermal expansion (CTE) of the pins can be controlled by using specific materials, such as copper (Cu), tungsten (W), molybdenum (Mo), silicon (Si), Si with through Si via (TSV). The pins can be compliant. The pins can be compliant based on included structure, such as bent beams, pogo pins, springs, etc. The pins can be both compliant and CTE-controlled by the choice of material and/or structure of the pins. The cross-sectional shape of the pins can be square, circular, or any other suitable shape. The size of the pins in the horizontal dimension can, for example. range from 0.1 millimeters (mm) to 10 mm.

Embodiments of the present disclosure include methods of forming or manufacturing a semiconductor structure with a heat spreader and pins extending between the heat spreader and a laminate layer and surrounding chiplets, which is adapted for thermal conduction from the chiplets in the laminate layer to the heat spreader. The method can include an operation of adding pins to a heat spreader. Another operation can be inserting the pins into or atop a laminate layer that surrounds a chiplet. Another operation can include surrounding the pins with a dielectric material in order to prevent electrical influence to wiring in the laminate layer. The pins can conduct heat from the chiplets in the laminate layer to a heat spreader.

Embodiments of the present disclosure can provide advantages that can be valuable to the semiconductor industry. Embodiments of the present disclosure can result in an enhancement of heat dissipation in semiconductor devices. Embodiments of the present disclosure can provide a thermal improvement or solution for semiconductor devices including 3Di and/or a BSPDN. Embodiments of the present disclosure can provide a thermal solution or improvement that does not significantly interfere with, or does not significantly affect, electrical and mechanical performance of the semiconductor devices. Embodiments of the present disclosure can include optimized locations of pins attached to a heat spreader that are located near one or more hot spots in the one or more chiplets in order to dissipate heat from the chiplets. Embodiments of the present disclosure can reduce the likelihood of thermal damage to chiplets or even failure of chiplets due to high temperatures relating to the chiplets. Embodiments of the present disclosure can provide appropriate placement of pins that can permit signal wiring in electronics packages and/or bridge chips for effective high bandwidth communication links while also supporting heat removal.

It is to be understood that the present disclosure will be described in terms of a given illustrative architecture; however, other architectures, structures, and process features and steps/blocks can be varied within the scope of the present disclosure. It should be noted that certain features cannot be shown in all figures for the sake of clarity. This is not intended to be interpreted as a limitation of any particular embodiment, or illustration, or scope of the claims.

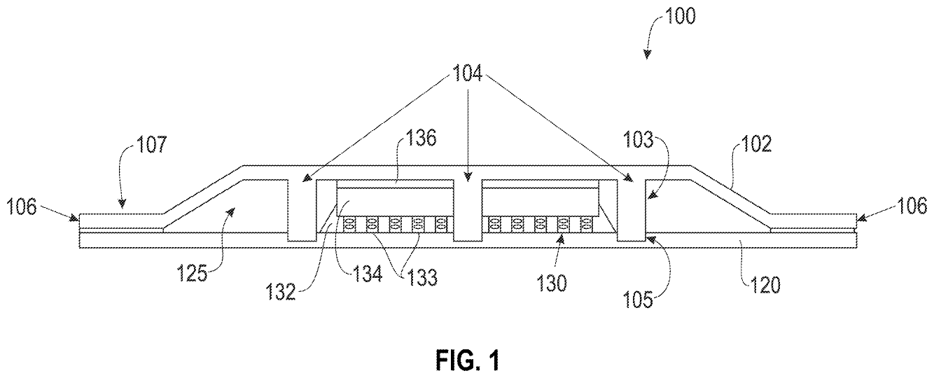

FIG. 1 illustrates a side, cut-away view of a semiconductor structure 100 including a heat dissipation mechanism, in accordance with an embodiment of the disclosure. The heat dissipation mechanism can include a heat spreader 102 and a plurality of pins 104 attached to the heat spreader 102 at a first end 103 of the pins 104. A second end 105 of the pins 104 can be inserted into a laminate layer 120. The pins 104 can be located around a chiplet 130, and the heat spreader 102 can be located above the chiplet 130. The pins 104 can conduct heat from the laminate layer 120 to the heat spreader 102. As shown, a space 125 between the laminate layer 120 and the heat spreader 102 can be formed in order to accommodate the chiplet 130. The heat spreader 102 can taper downward from the space 125 towards an outer perimeter portion 107 of the heat spreader 102 that can be attached to the laminate layer 120 by a sealband 106. The sealband 106 can be any suitable adhesive, such as an epoxy, used to adhere the heat spreader 102 to the laminate layer 120 around a perimeter of the heat spreader 102. The chiplet 130 can include an underfill layer 132 (or fillet), a device layer 134 and a thermal interface material (TIM) layer 136, as shown. The underfill layer 132 can be an adhesive and can attach the device layer 134 to the laminate layer 120 and can include solder portions 133. The TIM layer 136 can attach the device layer 134 to the heat spreader 102.

The chiplet 130, and other chiplets described herein, can include a plurality of stacked dies. The laminate layer 120 (or “laminate”), and other laminate layers described herein, can be a substate that includes a plurality of laminated layers of organic material, for example. The laminate layer 120 can include a core and/or can include conductive features (e.g., traces, vias, pads, etc.) to provide electrical routing through the laminate layer 120. Such conductive features in the laminate layer 120 are not shown for simplicity purposes.

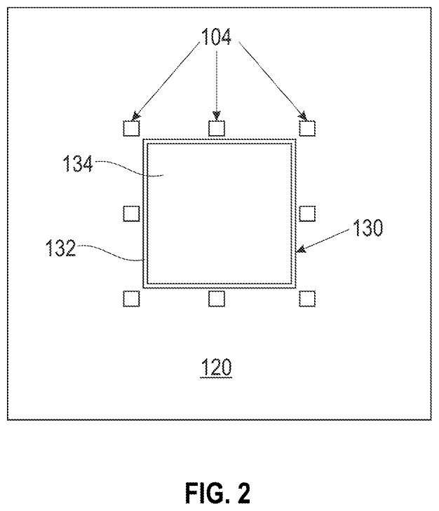

FIG. 2 illustrates a top-down view of the semiconductor structure 100 of FIG. 1, not including the heat spreader 102 (as in FIG. 1), in accordance with an embodiment of the disclosure. The chiplet 130 is shown with the devices layer 134 over the underfill layer 132. The chiplet 130 is surrounded by a plurality of pins 104 and, in particular, eight (8) pins 104 are included in the embodiment shown. Other numbers of pins 104, however, are also contemplated, and are not limited to those shown in the figures herein. The pins 104 are embedded in the laminate layer 120 at one end. Alternatively, the pins 104 can sit on top of the laminate layer 120. The plurality of pins 104 can contact an edge of the chiplet 130 rather than surround or be located at a distance from the chiplet 130. One of the pins 104 (near the top of the figure) is shown in contact with an edge of the chiplet 130. Any number of the pins 104 could be in contact with an edge of the chiplet 130, however, or close to the chiplet 130. In some embodiments, the chiplet 130 can include wiring (not shown) that can have a possibility of being interfered with by the pins 104 if they are located in contact with an edge of the chiplet 130. The present disclosure contemplates embodiments in which the pins 104 are located a distance away from the chiplet 130 and embodiments in which the pins 104 are located directly in contact with an edge of the chiplet 130. A range of a distance between the pins 104 and the chiplet 130 can be 0-5 mm, for example. If the pins 104 are in direct contact with the chiplet 130 that can possibly improve heat dissipation from the chiplet 130.

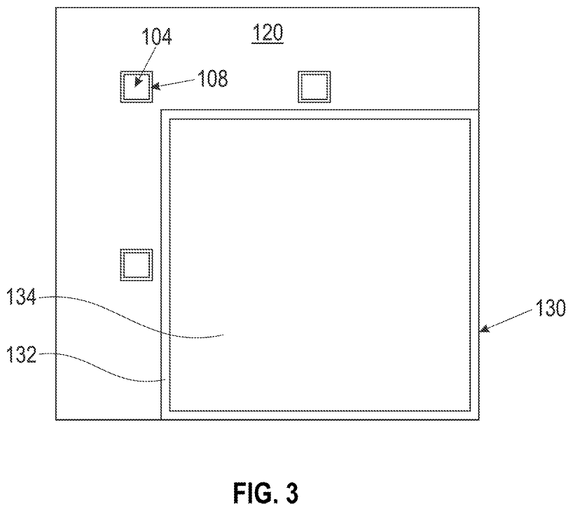

FIG. 3 illustrates a magnified portion of the top-down view of FIG. 2, in accordance with an embodiment of the disclosure. As shown, the pins 104 can be surrounded by a dielectric layer 108. The dielectric layer 108 can prevent electrical influence to wiring (not shown) in the laminate layer 120. In a semiconductor structure or assembly including the features shown in FIG. 3, the sealband 106, the underfill layer 132, the dielectric layer 108 and a thermal interface material (TIM) can be simultaneously cured at 150 degrees Celsius.

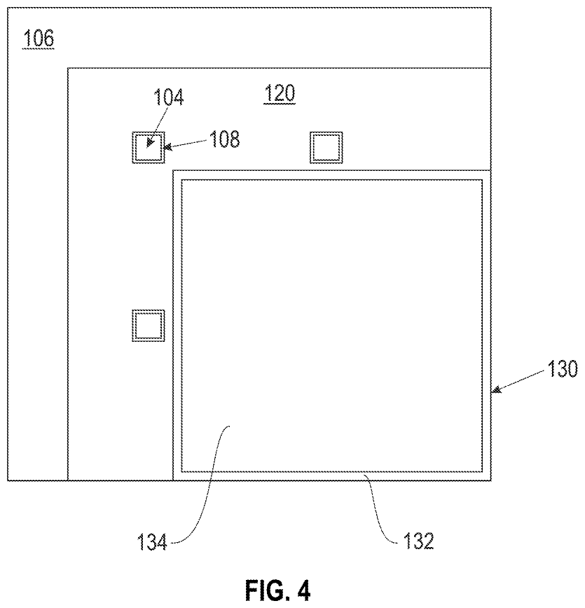

FIG. 4 illustrates a magnified portion of the top-down view of FIG. 2, in accordance with an embodiment of the disclosure. As shown, the laminate layer 120 can be shown with a sealband 122 atop the laminate layer 120 around a perimeter. A purpose of the sealband 106 can be to tightly bind a heat spreader (not shown) with the laminate layer 120. The pins 104 have the dielectric layer 108 around the pins 104. The dielectric layer 108 can be an underfill that binds the pins 104 with the laminate layer 120.

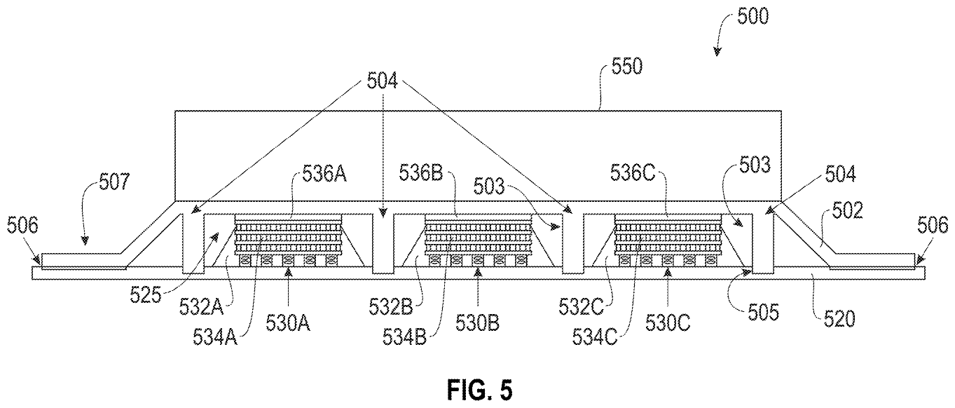

FIG. 5 illustrates a side, cut-away view of a semiconductor structure 500 including a heat dissipation mechanism, in accordance with an embodiment of the disclosure. The heat dissipation mechanism can include a heat spreader 502 and a plurality of pins 504 attached to the heat spreader 502 at a first end 503 of the pins 504. A second end 505 of the pins 504 can be inserted into a laminate layer 520, or, alternatively, resting atop the laminate layer 520. The pins 504 can be located around and between a plurality of chiplets 530A, 530B, 530C (three (3) are shown, but other suitable numbers are also contemplated), and the heat spreader 502 can be located above the chiplets 530A-C. The pins 504 can conduct heat from the laminate layer 520 to the heat spreader 502. As shown, a space 525 between the laminate layer 520 and the heat spreader 502 can be formed in order to accommodate the chiplets 530A-C. The heat spreader 502 can taper downward from the space 525 towards an outer perimeter portion 507 of the heat spreader 502 that can attach to the laminate layer 520 by a sealband 506. The sealband 506 can be any suitable adhesive, such as an epoxy, used to adhere the heat spreader 502 to the laminate layer 520 around a perimeter of the heat spreader 502. The chiplets 530A-C can each include an underfill layer 532A-C, a device layer 534A-C and a TIM layer 536A-C, respectively, as shown. The underfill layers 532A-C can attach each of the device layers 534A-C to the laminate layer 520. The TIM layers 536A-C can attach each of the device layers 534A-C to the heat spreader 502.

The heat spreader 502 with the pins 504 can dissipate at least some heat density from the chiplets 530A-C, etc. The heat spreader 502 and pins 504 can be applicable or used in 3Di, BSPDNs, for example, and other high-heat dissipating packages. The multiple pins 504 can support heat removal from one or more chiplets, such as 530A-C. The locations of the pins 504 can be optimized considering one or more hot spots within the one or more chiplets, such as 530A-C. The pins 504 do not significantly interfere with electrical and mechanical performance of the semiconductor structure 500. The heat spreader 502 with the pins 504 can be applied easily. Appropriate placement of the pins 504 can permit signal wiring while also supporting heat removal.

In the placement of the pins 504 (as in FIG. 5) or the pins 104 (as in FIG. 1), other considerations besides a hot spot relating to the chiplets, for example, can be taken into consideration. For example, a power and a ground wiring or grid, and/or decaps inductors and/or voltage regulators that are embedded in the semiconductor structure 100 can be taken into consideration. Also, surface mount or integrated chiplets and/or package structures can be taken into consideration when placing the pins 104, 504.

In FIG. 5, a heat sink 550 is included in the semiconductor structure 500. In some embodiments, a heat sink 550 can be included above the heat spreader 502 in order to remove heat. The heat sink 550 can be in direct contact with the heat spreader 502 or located near the heat spreader 502.

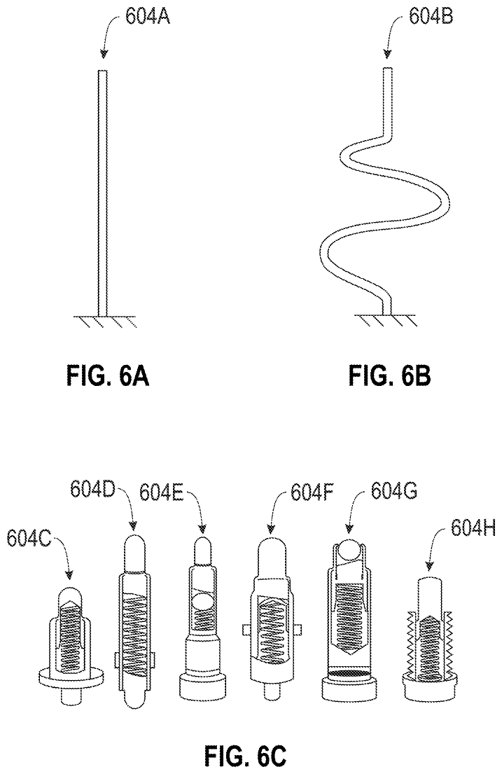

FIGS. 6A-6C illustrate examples of pins that can be included in a semiconductor structure including a heat dissipation mechanism, in accordance with an embodiment of the disclosure. FIG. 6A illustrates a pin 604A in a straight or beam-like configuration. FIG. 6B illustrates a pin 604B in a bent or shaped configuration. The bend or shape of the pin 604B can include any suitable shape. FIG. 6C includes a variety of example pins 604C, 604D, 604E, 604F, 604G and 604H that are known as “pogo pins.” The pogo pins include a spring in order to provide compliance. The pins can be described as “complaint” or flexible. The definition of compliance, or being compliant, is being capable of being significantly displaced when a load is applied. Compliance is the inverse of stiffness. The pins can include structure and/or material that makes the pins capable of being compliant. The variety of pins shown in FIGS. 6A-6C are examples of ways in which thermal-mechanical stress can be reduced. Due to heat and mechanical stresses, a semiconductor package can flex, contract or expand. Thus, in some embodiments of the present disclosure, compliancy in the pins can be important. Additionally, or alternatively, the pins can have a CTE. The pins described herein can have a CTE that can be controlled by the material chosen for the pins. Some suitable materials can include Co, Tungsten (W), Molybdenum (Mo), silicon (Si), Si with a through Si Via (TSV), etc. A cross-sectional shape of the pins can be circular, as shown, square, or any other suitable shape. A horizontal dimension of the pins (i.e., a diameter of a cross-section of the pins) can be about 0.1 mm to about 10 mm, for example.

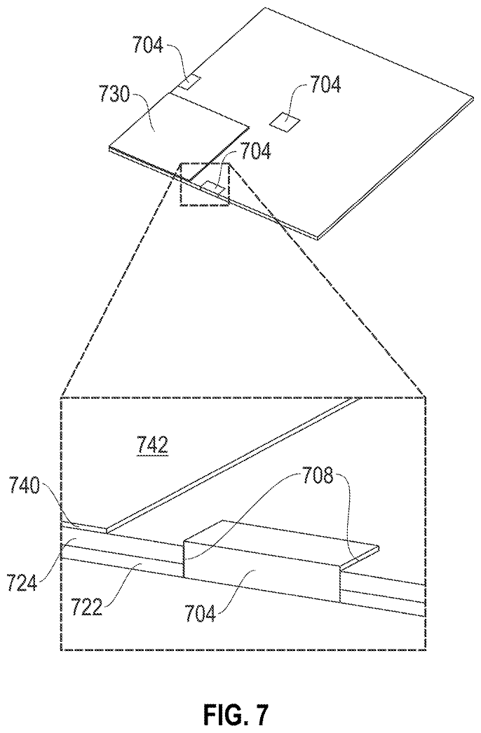

FIG. 7 illustrates a perspective view of a portion (approximately a quarter) of a semiconductor structure 700 and a close-up view of another portion of the semiconductor structure, used in simulations, in accordance with an embodiment of the disclosure. Five (5) examples or simulations (i.e., simulations 1-5) were carried out on the portion of the semiconductor structure 400 shown, which will be described in more detail below. Neither a heat spreader nor a heat sink was represented in the simulations, so a heat transfer coefficient was applied on the top of the pins corresponding to a heat spreader and a heat sink. The heat transfer coefficient of 20,000 watts per square meter per Kelvin (W/m²K) was set on the top surfaces of pins 704. Heat is normally generated at a lower portion of chiplets where transistors are located. In the simulations, a chiplet was not included, however an interconnection layer 740 was included that would normally be located below a chiplet. The interconnection layer 740 was made of solder and underfill material. The interconnection layer 740 was located in one corner of the portion of the semiconductor structure 700 having length and width dimensions of 10 mm by 10 mm. The interconnection layer 740 represented where a chiplet (not included) would be located, A back end-of-line (BEOL) layer 742 was applied atop the interconnection layer 740. The BEOL layer 742 was 10 micrometers (μm) thick, and the interconnection layer 740 was 60 μm thick. The portion of the semiconductor structure 700 also included a power and ground plane layer 722 and a build-up layer 724, stacked together, with length and width dimensions of 25 mm by 25 mm. The power and ground plane layer 722 and the build-up layer 724 were used in the portion of the semiconductor structure 700 in order to replicate and simplify a laminate layer (such as the laminate layer 120 and the laminate layer 520 in FIGS. 1 and 5, respectively). A maximum temperature of a chiplet (not used) would be about 85 degrees Celsius (° C.), with an ambient temperature being about 25° C.

A single and two halves of pins 704 were included in the portion of semiconductor structure 700. The pins 704 (whole) had both length and width dimensions of 2 mm, 3 mm or 4 mm. The pins 704 had a layer of dielectric material layer 708 on each side of the pins 704 and located between the pins 704 and the power and ground plane layer 722 and the build-up layer 724. A total thickness of the power and ground plane layer 722 was 150 μm to 400 μm and includes a copper (Cu) plane with a dielectric and Cu fill.

Table 1, below, includes results from a first simulation using the portion of the semiconductor structure 700 of FIG. 7. The table reflects results when different pin 704 dimensions and also different thicknesses of the power and ground plane layer 722 were used. The simulation included a bottom of a 5-die-high 3Di. The simulation tested how much heat could be managed at the interconnection layer 740 (which would be similar to a bottom of a chiplet, if present) using different pin dimensions. Heat density in the simulation was set, or applied, at the top of the interconnection layer 740. The applied, or generated, heat conducted through the interconnection layer 740, the build-up layer 724, and the power and ground plane layer 722 and to the pins 704. The heat flow in the simulation was from the interconnection layer 740 through to the pins 704. The heat transfer coefficient was set at the top of the pins 704. According to the simulation results, an additional heat density of 4.5 watts per square centimeter (W/cm²) was managed. A maximum chiplet temperature decreased by 4.71° C. in one of the simulations using the largest pin 704 dimension (which was 5 mm by 5 mm) and the thickest power and ground plane layer 722 (which was 400 μm, or 320 μm just in a core). Therefore, the manageable heat density increased as the pin dimension increased and as the thickness of the copper plane (in the power and ground plane layer 722) increased. The manageable heat density was transformed using a calculation in order to be represented by a maximum chiplet temperature. Thus, the maximum chiplet temperature decreased as the pin 704 dimension increased and as the thickness of the copper plane (in the power and ground plane layer 722) increased. A software program called ANSYS™ was used in the simulation, in order to simulate a bottom chiplet of a 5-die-high 3Di configuration, meaning five (5) die stacked on top of one another.

TABLE 1
Simulation 1 Results-Bottom Chiplet of 5-die-high 3Di.

| | | | | When it is |
|---|---|---|---|---|
| | Total thickness | Thickness of | | transformed to |
| | of power and | power and | | maximum |
| Pin dimension | ground plane | ground plane in | Manageable heat | chiplet |
| (mm × mm) | (μm) | a core (μm) | density (W/cm²) | temperature (° C.) |
| NA | 0 | 0 | 52.4 | 85.00 |
| 2 mm × 2 mm | 150 | 70 | +1.5 | 83.34 |
| | 200 | 120 | +1.7 | 83.08 |
| | 300 | 220 | +2.1 | 82.67 |
| | 400 | 320 | +2.4 | 82.32 |
| 3 mm × 3 mm | 150 | 70 | +2.0 | 82.82 |
| | 200 | 120 | +2.3 | 82.49 |
| | 300 | 220 | +2.9 | 81.86 |
| | 400 | 320 | +3.4 | 81.34 |
| 5 mm × 5 mm | 150 | 70 | +2.4 | 82.35 |
| | 200 | 120 | +2.9 | 81.86 |
| | 300 | 220 | +3.7 | 81.01 |
| | 400 | 320 | +4.5 | 80.29 |

Tables 2-5 below includes results from second, third, fourth and fifth simulations using the portion of the semiconductor structure 700 of FIG. 7, and as described above with regard to the Table 1 results. However, ANSYS™ was used to simulate a 4 die-high 3Di, a 3 die-high 3Di, a 2die-high 3Di, and a no 3Di configuration (a 2D chip), and the results are summarized in the tables below, respectively. In the case of the 2D chip configuration, ANSYS™ was used with material properties to calculate the values in the table (Table 5). For the 3Di cases, a numerical calculation was performed based on the simulation using ANSYS™. In addition, the following assumptions of the thermal resistance of each chip was assumed: the BEOL layer had a thermal resistance of 0.1 Kcm²/W (1 W/mK, 10 μm thick), the interconnecting layer had a thermal resistance of 0.058 Kcm²/W (4.3 W/mK, 25 μm thick), and the chiplet had a thermal resistance of 0.0003 Kcm²/W (148 W/mK, 50 μm thick). Overall, the results of all of the simulations together showed that use of the heat dissipation mechanism of the present disclosure was more effective and efficient in removing heat from a chiplet having a die configuration that had more layers or dies over one with fewer dies. A presence of the pins was, therefore, more effective with a chiplet including a stack of dies rather than fewer dies.

TABLE 2
Simulation 2 Results-Bottom Chiplet of 4-die-high 3Di.

| | | | | When it is |
|---|---|---|---|---|
| | Total thickness | Thickness of | | transformed to |
| | of power and | power and | | maximum |
| Pin dimension | ground plane | ground plane in | Manageable heat | chiplet |
| (mm × mm) | (μm) | a core (μm) | density (W/cm²) | temperature (° C.) |
| NA | 0 | 0 | 61.0 | 85.00 |
| 2 mm × 2 mm | 150 | 70 | +1.5 | 83.57 |
| | 200 | 120 | +1.7 | 83.34 |
| | 300 | 220 | +2.1 | 82.98 |
| | 400 | 320 | +2.4 | 82.69 |
| 3 mm × 3 mm | 150 | 70 | +2.0 | 83.12 |
| | 200 | 120 | +2.3 | 82.83 |
| | 300 | 220 | +2.9 | 81.28 |
| | 400 | 320 | +3.4 | 81.83 |
| 5 mm × 5 mm | 150 | 70 | +2.4 | 82.71 |
| | 200 | 120 | +2.9 | 82.28 |
| | 300 | 220 | +3.7 | 81.54 |
| | 400 | 320 | +4.5 | 80.91 |

TABLE 3
Simulation 3 Results-Bottom Chiplet of 3-die-high 3Di.

| | | | | When it is |
|---|---|---|---|---|
| | Total thickness | Thickness of | | transformed to |
| | of power and | power and | | maximum |
| Pin dimension | ground plane | ground plane in | Manageable heat | chiplet |
| (mm × mm) | (μm) | a core (μm) | density (W/cm²) | temperature (° C.) |
| NA | 0 | 0 | 72.9 | 85.00 |
| 2 mm × 2 mm | 150 | 70 | +1.5 | 83.80 |
| | 200 | 120 | +1.7 | 83.61 |
| | 300 | 220 | +2.1 | 83.31 |
| | 400 | 320 | +2.4 | 83.05 |
| 3 mm × 3 mm | 150 | 70 | +2.0 | 83.42 |
| | 200 | 120 | +2.3 | 83.17 |
| | 300 | 220 | +2.9 | 82.71 |
| | 400 | 320 | +3.4 | 82.32 |
| 5 mm × 5 mm | 150 | 70 | +2.4 | 83.08 |
| | 200 | 120 | +2.9 | 82.71 |
| | 300 | 220 | +3.7 | 82.08 |
| | 400 | 320 | +4.5 | 81.54 |

TABLE 4
Simulation 4 Results-Bottom Chiplet of 2-die-high 3Di.

| | | | | When it is |
|---|---|---|---|---|
| | Total thickness | Thickness of | | transformed to |
| | of power and | power and | | maximum |
| Pin dimension | ground plane | ground plane in | Manageable heat | chiplet |
| (mm × mm) | (μm) | a core (μm) | density (W/cm²) | temperature (° C.) |
| NA | 0 | 0 | 90.7 | 85.00 |
| 2 mm × 2 mm | 150 | 70 | +1.5 | 84.03 |
| | 200 | 120 | +1.7 | 83.88 |
| | 300 | 220 | +2.1 | 83.63 |
| | 400 | 320 | +2.4 | 83.42 |
| 3 mm × 3 mm | 150 | 70 | +2.0 | 83.72 |
| | 200 | 120 | +2.3 | 83.52 |
| | 300 | 220 | +2.9 | 83.14 |
| | 400 | 320 | +3.4 | 82.83 |
| 5 mm × 5 mm | 150 | 70 | +2.4 | 83.44 |
| | 200 | 120 | +2.9 | 83.15 |
| | 300 | 220 | +3.7 | 82.63 |
| | 400 | 320 | +4.5 | 82.19 |

TABLE 5
Simulation 5 Results-Bottom Chiplet with No 3Di (2D).

| | Total thickness | Thickness of | | When it is |
|---|---|---|---|---|
| | of power and | power and | | transformed to |
| Pin dimension | ground plane | ground plane in | Manageable heat | maximum chip |
| (mm × mm) | (μm) | a core (μm) | density (W/cm²) | temperature (° C.) |
| NA | 0 | 0 | 120 | 85.00 |
| 2 mm × 2 mm | 150 | 70 | +1.5 | 84.26 |
| | 200 | 120 | +1.7 | 84.15 |
| | 300 | 220 | +2.1 | 83.96 |
| | 400 | 320 | +2.4 | 83.80 |
| 3 mm × 3 mm | 150 | 70 | +2.0 | 84.03 |
| | 200 | 120 | +2.3 | 83.88 |
| | 300 | 220 | +2.9 | 83.59 |
| | 400 | 320 | +3.4 | 83.34 |
| 5 mm × 5 mm | 150 | 70 | +2.4 | 83.82 |
| | 200 | 120 | +2.9 | 83.59 |
| | 300 | 220 | +3.7 | 83.19 |
| | 400 | 320 | +4.5 | 82.85 |

The simulations 1-5 above, with regard to FIG. 7 and Tables 1-5, related to the semiconductor structure 700 with heat being considered only to be generated by a bottom chip. The simulations 6-8, described below, related to a 3-die-high 3Di, and addressed a top chip, a middle chip and a bottom chip.

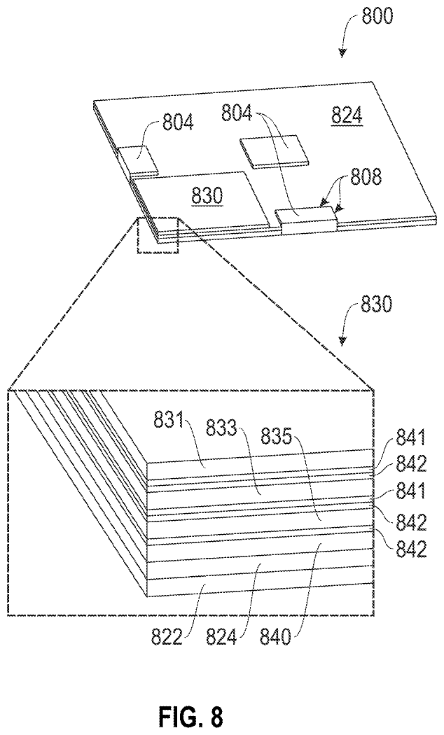

FIG. 8 illustrates a perspective view of a portion (approximately a quarter) of a semiconductor structure 800 of a heat dissipation mechanism, and a close-up view of another portion of the semiconductor structure, in accordance with an embodiment of the disclosure. Three (3) examples or simulations (i.e., simulations 6-8) were carried out on the portion of the semiconductor structure 800 shown, which will be described in more detail below. The portion of the semiconductor structure 800 included a stack of a power and ground plane layer 822 and a build-up layer 824 having length and width dimensions of 25 mm by 25 mm. A multiple chip portion 830 was located in one corner of the stack of the power and ground plane layer 822 and the build-up layer 824 and had length and width dimensions of 10 mm by 10 mm. The multiple chip portion 830 included a top chip 831, a middle chip 833, and a bottom chip 835 that each was made of silicon and that had a thickness each of 50 μm. The multiple chip portion 830 included three (3) back end-of-line (BEOL) layers 842 below each of the three (3) chips 831, 833, 835, and an interconnection layer 840, which included solder and under fill material, that was located below the bottom chip 835. Other interconnection layers 841 were located under each BEOL layer 842 and were 25 μm thick. The BEOL layers 842 were 10 μm thick, and the interconnection layer 840 was 60 μm thick. A maximum temperature of the multiple chip portion 830 was 85° C., with an ambient temperature being 25° C. A single and two halves of pins 804 were included. The pins 804 (whole) had both length and width dimensions of 5 mm. The pins 804 had a dielectric material layer 808 between the pins 804 and the power and ground plane layer 822 and the build-up layer 824. A heat transfer coefficient of 20,000 W/m²K was set on the top surfaces of the multiple chip portion 830 and the pins 804. The power and ground plane layer 822 included a Cu plane with a dielectric and Cu fill and was 400 μm thick. The build-up layer 824 was 220 μm thick.

Table 6, below, includes results from a sixth simulation using the portion of the semiconductor structure 800 of FIG. 8. A bottom surface of the top chip 831 of the multiple chip portion 830 in the simulation was evaluated for heat density using the heat dissipation mechanism of the disclosure and without the heat dissipation mechanism of the disclosure. The other two chips, the middle chip 833 and the bottom chip 835, had a heat density of 10 W/cm². The chip was a 3-die-high 3Di. Overall, the results show that the manageable heat density of the top chip 831 was increased using the heat dissipation mechanism of the disclosure.

TABLE 6
Simulation 6 results.

| | | Total | | | |
|---|---|---|---|---|---|
| | | Thickness of | Thickness of | | When it is |
| | | Power and | Power and | Manageable | Transformed |
| | Pin | Ground Plane | Ground Plane | Heat Density | to Max. Chip |
| | Dimension | in a Core | in a Core | of Top Chip | Temp. of Top |
| Case | (mm × mm) | (μm) | (μm) | (W/m²K) | Chip (° C.) |
| Without this | NA | 0 | 0 | 89.8 | 85 |
| disclosure | | | | | |
| With this | 5 mm × 5 mm | 400 | 320 | 94.5 | 82.0 |
| disclosure | | | | | |

Table 7, below, includes results from a seventh simulation using the portion of the semiconductor structure 800 of FIG. 8. A bottom surface of the middle chip 833 of the multiple chip portion 830 in the simulation was evaluated for heat density using the heat dissipation mechanism of the disclosure and without the heat dissipation mechanism of the disclosure. The other two chips, the top chip 831 and the bottom chip 835, had a heat density of 10 W/cm². The chip was a 3-die-high 3Di. Overall, the results show that the manageable heat density of the middle chip 833 was increased using the heat dissipation mechanism of the disclosure.

TABLE 7
Simulation 7 results.

| | | Total | | | |
|---|---|---|---|---|---|
| | | Thickness of | Thickness of | Manageable | When it is |
| | | Power and | Power and | Heat Density | Transformed |
| | Pin | Ground Plane | Ground Plane | of Middle | to Max. Chip |
| | Dimension | in a Core | in a Core | Chip | Temp. of Top |
| Case | (mm × mm) | (μm) | (μm) | (W/m²K) | Chip (° C.) |
| Without this | NA | 0 | 0 | 70.0 | 85 |
| disclosure | | | | | |
| With this | 5 mm × 5 mm | 400 | 320 | 73.8 | 81.9 |
| disclosure | | | | | |

Table 8, below, includes results from a seventh simulation using the portion of the semiconductor structure 800 of FIG. 8. A bottom surface of the bottom chip 835 of the multiple chip portion 830 in the simulation was evaluated for heat density using the heat dissipation mechanism of the disclosure and without the heat dissipation mechanism of the disclosure. The other two chips, the top chip 831 and the middle chip 833, had a heat density of 10 W/cm². The chip was a 3-die-high 3Di. Overall, the results show that the manageable heat density of the bottom chip 835 was increased using the heat dissipation mechanism of the disclosure.

TABLE 8
Simulation 8 results.

| | | Total | | | |
|---|---|---|---|---|---|
| | | Thickness of | Thickness of | Manageable | When it is |
| | | Power and | Power and | Heat Density | Transformed |
| | Pin | Ground Plane | Ground Plane | of Bottom | to Max. Chip |
| | Dimension | in a Core | in a Core | Chip | Temp. of Top |
| Case | (mm × mm) | (μm) | (μm) | (W/m²K) | Chip (° C.) |
| Without this | NA | 0 | 0 | 58.5 | 85 |
| disclosure | | | | | |
| With this | 5 mm × 5 mm | 400 | 320 | 61.7 | 81.9 |
| disclosure | | | | | |

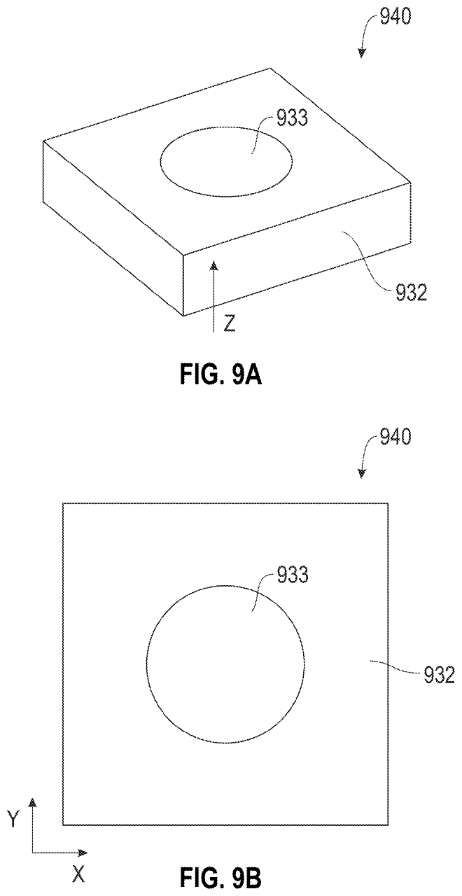

FIGS. 9A-9B illustrate a perspective view and a top view, respectively, of a a model of an interconnection layer 940 of a semiconductor structure, in accordance with an embodiment of the disclosure. The interconnection layer 940 shown includes an underfill portion 932 and a solder portion 933. The solder portion 933 had a circular cross-sectional shape, as shown, and was located near or at a center of the underfill portion 932.

Parameters and derived equivalent thermal conductivity of the interconnection layer 940 are included, respectively, in Table 9 and Table 10 below. The dimensions of the interconnection layer 940 had a diameter of the solder portion 933 of 75 μm. The underfill portion 932 had a dimension of 150 μm in the x and y directions. A thickness of the underfill portion 932 in the z direction was 20 μm. The calculated thermal conductivities of the interconnection layer 940, in Table 10 were used in the calculations in the Simulations 1-8 (for interconnection layers 740, 840 in FIGS. 7 and 8, respectively) detailed above.

TABLE 9
Parameters of Interconnection Layer Used in Simulations.

| | X Direction | Y Direction | Z Direction |
|---|---|---|---|
| | (W/mK) | (W/mK) | (W/mK) |
| Solder | 21 | 21 | 21 |
| Underfill | 0.4 | 0.4 | 0.4 |

TABLE 10
Derived Equivalent Thermal Conductivity of Interconnection Layer.

| | X Direction (W/mK) | Y Direction (W/mK) | Z Direction (W/mK) |
|---|---|---|---|
| Interconnection layer − | 0.6 | 0.6 | 4.3 |
| 2 (Solder + | | | |
| Underfill) | | | |

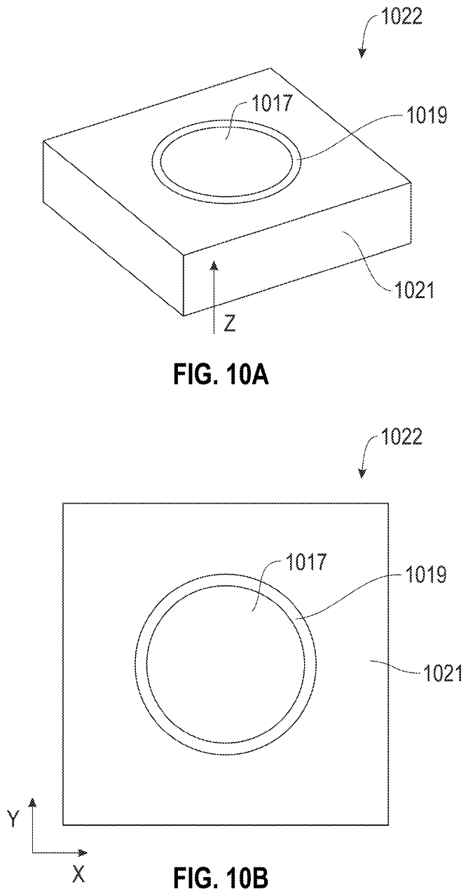

FIGS. 10A-10B illustrate a perspective view and a top view, respectively, of an example of a power and ground plane layer 1022 of a semiconductor structure, including a Cu plane 1021, a Cu fill 1017 surrounded by a build-up dielectric layer 1019, in accordance with an embodiment of the disclosure. The Cu fill 1017 had a circular cross-sectional shape, as shown, and was located near or at a center of the Cu plane 1021.

Parameters and derived equivalent thermal conductivity of the power and ground plane layer 1022 are included, respectively, in Table 11 and Table 12 below. The dimensions of the Cu fill 1017 used in the tenth simulation had a diameter of 75 μm. The cross-sectional thickness of the build-up dielectric layer 1019 was 7.5 μm. The Cu plane 1021 had a dimension of 150 μm in the x and y directions. A thickness of the Cu plane 1021 in the z direction was between 100-500 μm. The calculated thermal conductivities of the power and ground plane layer 1022, in Table 10 were used in the calculations in the Simulations 1-8 (for power and ground plane layers 722, 822 in FIGS. 7 and 8, respectively) detailed above.

TABLE 11
Parameters of Power and Ground Plane Layer Used in Simulations.

| | X Direction (W/mK) | Y Direction (W/mK) | Z Direction (W/mK) |
|---|---|---|---|
| Cu | 398 | 398 | 398 |
| Build Up Dielectric | 0.2 | 0.2 | 0.2 |

TABLE 12
Derived Equivalent Thermal Conductivity of the Power and Ground Plane Layer.

| | X Direction (W/mK) | Y Direction (W/mK) | Z Direction (W/mK) |
|---|---|---|---|
| Cu Plane with | 223.8 | 223.8 | 362.4 |
| Dielectric and Cu Fill | | | |
| Dielectric | 0.2 | 0.2 | 0.2 |

Table 13 below provides thermal conductivity values for semiconductor materials or layers (such as in FIGS. 7 and 8) that were used in calculations relating to Simulations 1-8 described above.

TABLE 13
Thermal Conductivity Parameters of Materials/Layers
Used in Simulations.

| | Thermal | Thermal | Thermal |
|---|---|---|---|
| | Conductivity | Conductivity | Conductivity |
| | (W/mK) in X | (W/mK) in Y | (W/mK) in Z |
| Material | Direction | Direction | Direction |
| Cu | 398 | 398 | 398 |
| Solder | 21 | 21 | 21 |
| BEOL | 15 | 15 | 1 |
| Build Up Layer | 15 | 15 | 1 |
| Underfill | 0.4 | 0.4 | 0.4 |

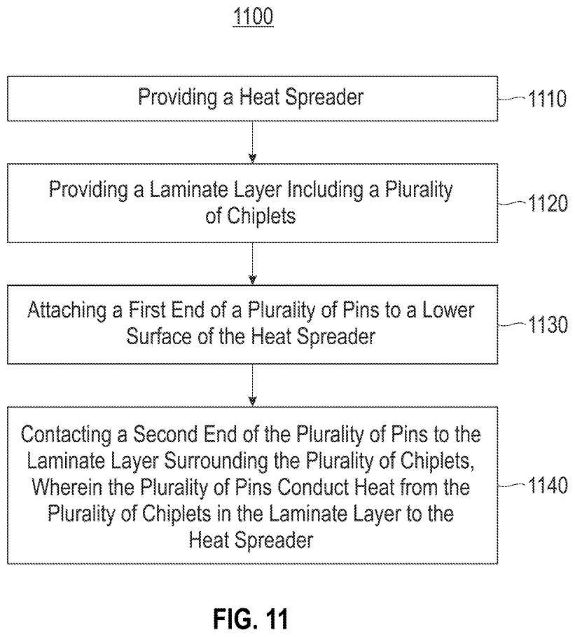

FIG. 11 illustrates a flow chart of a method 1100 of making or manufacturing a semiconductor structure, in accordance with an embodiment of the disclosure. An operation 1110 of the method 1100 is providing a heat spreader. Another operation 1120 is providing a laminate layer including a plurality of chiplets. Yet another operation 1130 is attaching a first end of a plurality of pins to a lower surface of the heat spreader. An additional operation 1140 is contacting a second end of the plurality of pins to the laminate layer surrounding the plurality of chiplets, wherein the plurality of pins conduct heat from the plurality of chiplets in the laminate layer to the heat spreader. The method 1100 can also include operations of providing a heat sink and contacting the heat sink with an upper surface of the heat spreader.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.”

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. A structure comprising:
at least one chiplet;
a heat spreader located over the at least one chiplet;
a laminate located under the at least one chiplet; and
at least one pin extending between the heat spreader and the laminate and located near the at least one chiplet,
wherein the at least one pin is adapted to dissipate heat from the at least one chiplet.

2. The structure of claim 1, wherein a first end of the at least one pin is connected to the heat spreader and a second end of the at least one pin is inserted into the laminate.

3. The structure of claim 1, wherein the at least one pin includes a plurality of pins that surround the at least one chiplet.

4. The structure of claim 1, wherein the heat spreader is thermally coupled to the at least one chiplet by the at least one pin.

5. The structure of claim 1, wherein the at least one pin includes a plurality of pins that are adapted to remove heat from the at least one chiplet.

6. The structure of claim 1, wherein the at least one pin contacts the at least one chiplet.

7. The structure of claim 1, further comprising:
a layer of dielectric material surrounding each of the at least one pin.

8. The structure of claim 1, wherein a first end of the at least one pin is connected to the heat spreader and a second end of the at least one pin sits on top of the laminate.

9. The structure of claim 1, wherein the at least one pin includes a plurality of pins and locations of the plurality of pins are optimized considering one or more hot spots in the at least one chiplet.

10. The structure of claim 1, wherein the at least one pin is compliant.

11. The structure of claim 10, wherein the at least one pin includes a bent beam configuration or a spring shape.

12. The structure of claim 10, wherein the at least one pin includes a material selected from a group consisting of copper, tungsten, molybdenum, or silicon.

13. The structure of claim 1, wherein a cross-sectional shape of the at least one pin is square or circular.

14. The structure of claim 1, wherein a diameter of the at least one pin is in a range of 0.1 millimeters (mm) to 10 mm.

15. A system comprising:
a plurality of chiplets;
a heat spreader located over the plurality of chiplets;
a laminate located under the plurality of chiplets;
a heat sink located over the heat spreader; and
a plurality of pins extending between the heat spreader and the laminate and located near the plurality of chiplets,
wherein the plurality of pins are adapted to dissipate heat from the plurality of chiplets.

16. The system of claim 15, wherein each of the plurality of pins contacts one of the plurality of chiplets.

17. The system of claim 15, further comprising:
a layer of dielectric material surrounding each of the plurality of pins.

18. The system of claim 15, wherein the plurality of pins are compliant.

19. A method comprising:
providing a heat spreader;
providing laminate layer including a plurality of chiplets;
attaching a first end of a plurality of pins to a lower surface of the heat spreader; and
contacting a second end of the plurality of pins to the laminate layer surrounding the plurality of chiplets,
wherein the plurality of pins conduct heat from the plurality of chiplets in the laminate layer to the heat spreader.

20. The method of claim 19, further comprising:
providing a heat sink; and
contacting the heat sink with an upper surface of the heat spreader.
